(19) United States
(12) Patent Application Publication
(10) Pub. No.: US 2009/0294952 A1
(43) Pub. Date: Dec. 3, 2009

(54) CHIP PACKAGE CARRIER AND FABRICATION METHOD THEREOF

(75) Inventors: Chi Chih Lin, Pingihen City (TW); Bo Sun, Pingihen City (TW); Hung Jen Wang, Gueishan Township (TW); Jen Feng Tseng, Jhongli City (TW)

Correspondence Address: ESCHWEILER & ASSOCIATES, LLC;NATIONAL CITY BANK BUILDING, 629 EUCLID AVE., SUITE 1000, CLEVELAND, OH, 44114, US

(73) Assignee: Taiwan Solutions Systems Corp., Hsinchu City (TW)

(21) Appl. No.: 12/128,107

(22) Filed: May 28, 2008

(51) Int. Cl. H01L 23/04; H01L 21/02; H01L 21/44

(52) U.S. Cl. 257/698; 438/121; 438/612; 257/E23.079; 257/E21.002; 257/E21.597

(57) ABSTRACT

The present invention discloses a chip package carrier and a fabrication method, which have the advantages of high reliability, thickness reduction and the scale reduction. The carrier and the method uses blind holes., which penetrates the substrate but external traces and external bonding pads, which cover the external traces. A chip can be installed and encapsulated directly on a first surface.

### BACKGROUND OF THE INVENTION

1. Field of the Invention

The present invention relates to a chip package carrier, which, in particular uses blind hole to connect the circuits of chips and external devices.

2. Description of the Related Art

In chip packaging, a chip is protected by encapsulating the chip in a carrier, which uses internal traces and external traces on a substrate to communicate with external circuits. The internal traces and external traces communicate with each other via through-holes. Then, internal bonding pads and external bonding pads disposed on the internal traces and external traces to connect the chip circuits and external circuits, respectively. The internal traces, external traces and through-holes can be protected by covering a solder mask, and the chip is connected to the internal bonding pads by conductive components. At last, the chip and related components are encapsulated with a molding compound.

However, it is easy to crash the electric conduction of external traces, internal traces and through-holes to degrade the reliability of a package structure due to the humidity permeation, which permeates through the space between the solder mask and traces. Besides, it is hard to decrease the thickness of the package structure to reach the demand of thinization, especially, for a mult-layer carrier. Further, it is hard to reduce the carrier size to satisfy the demand of miniaturation due to the seperated arragement of the through-holes, the internal traces, the external traces and the bonding pads.

Therefore, it is very important to redesign the through-holes to reach the demands of high reliability, thickness reduction and scale reduction.

### SUMMARY OF THE INVENTION

One objective of the present invention is to provide a chip package carrier, which has the advantages of high reliability, thickness reduction and scale reduction. The carrier uses blind holes to connect internal traces with external traces. The internal bonding pads and external bonding pads cover the internal traces and the external traces, respectively. The the internal traces and external tracescan be conducted by disposing a conductive material in the blind holes.

Another objective of the present invention is to provide a method of fabricating a chip package carrier having the blind holes, which has the advantage of simplifying the fabrication process. The method comprises steps of forming a metal layer on a second surface of a substrate, forming blind holes in the substrate, wherein the blind holes penetrates the substrate but the metal layer, forming external traces by processing the metal layer, wherein the external traces cover the blind holes, and covering the external traces with external bonding pads to complete a carrier.

It is a method to connect the chip and the external traces via the blind hols when the chip is installed on a first surface of the substrate, and to encapsulate the chip and the related components by a molding compound. Another method is to form internal traces on the first surface and to form internal bonding pads cover the internal traces first, and then to connect the chip to the internal bonding pads, and finally to encapsulate the chip and the related components by a molding compound.

Alternatively, the chip can be installed on the second surface of the carrier and connects to the external bonding pads by conductive components, and then to encapsulate the chip and related components by a molding compound.

### BRIEF DESCRIPTION OF THE DRAWINGS

FIGS. 1a-1c are diagrams schematically showing the package structures, which are installed on the chip package carriers according to embodiments of the present invention;

FIGS. 2a-2c are diagrams schematically showing the package structures, which are installed on the chip package carriers according to other embodiments of the present invention;

FIGS. 3a-3d are sectional views schematically showing the process of the fabrication method of a chip package carrier according to one embodiment of the present invention; and

FIGS. 4a-4e are sectional views schematically showing the process of the the fabrication method of a chip package carrier according to another embodiment of the present invention.

### DETAILED DESCRIPTION OF THE INVENTION

Accompanying with drawings, the description of this invention is followed to convince the spirit of this invention.

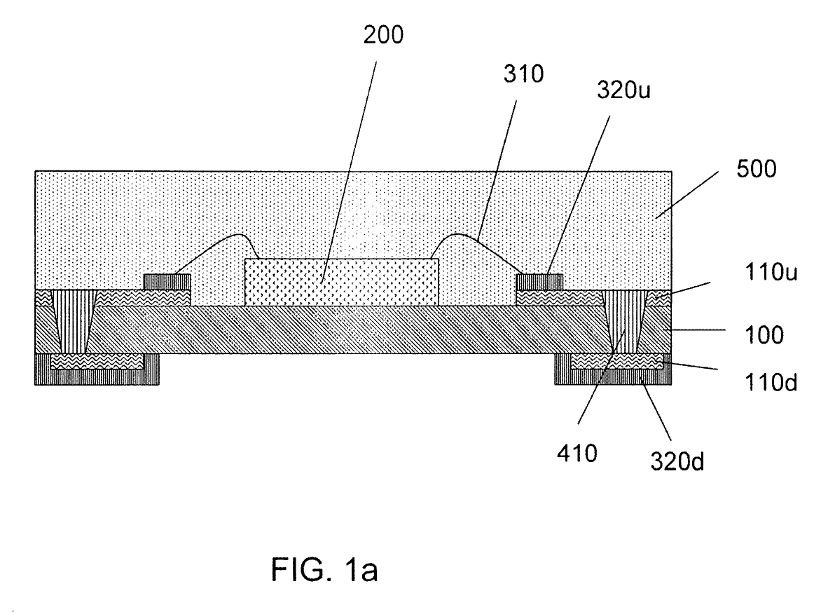

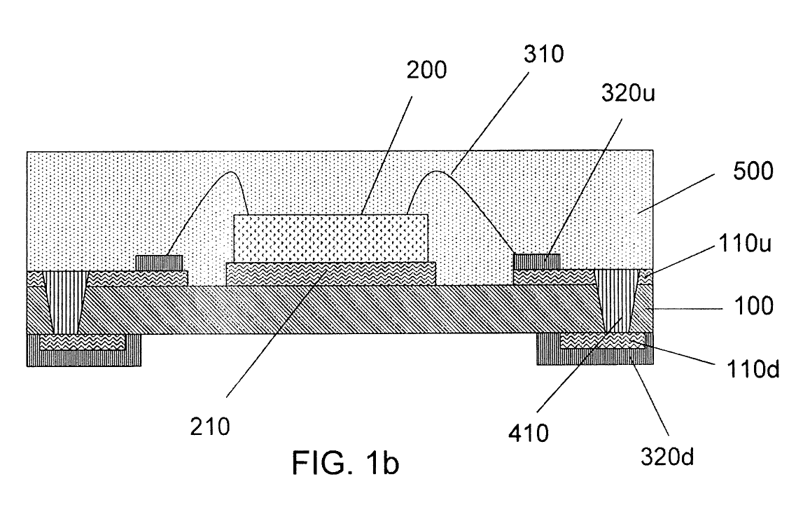

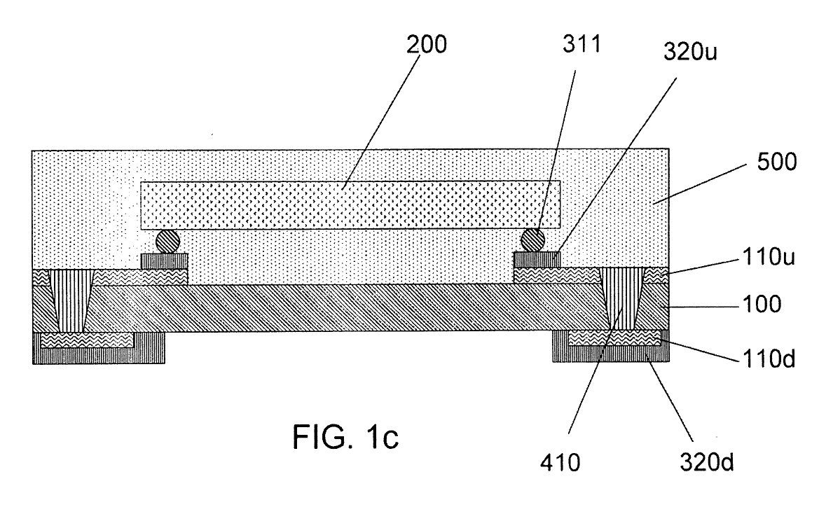

FIGS. 1a-1c show the package structures of utilizing the chip package carriers according to embodiments of this invention.

FIG. 1a shows an embodiment. Internal traces 110u connect with external traces 110d via a conductive material set inside blind holes 410. From a first surface of the substrate 100, the blind hole 410 penetrates the substrate 100 and the internal trace 110u on but the external trace 110d on a second surface of the substrate 100, so called blind hole. External bonding pads 320d cover the external traces 110d, and internal bonding pads 320u are formed on the internal traces 110u. A chip 200 is installed on the first surface and between two internal traces 110u and connected to the internal bonding pads 320u via conductive components, such as metallic bonding wires. A molding compound 500 encapsulates the chip 200, conductive components 310, internal bonding pads 320u and internal traces 110u to complete a package structure.

The embodiment in FIG. 1b is a variant of the embodiment in FIG. 1a, where the difference is a chip base 210 interposed between the chip 200 and the substrate 100, and another variant, shown in FIG. 1c, where the difference is the conductive balls 311 instead of the metallic bonding wires in FIG. 1a.

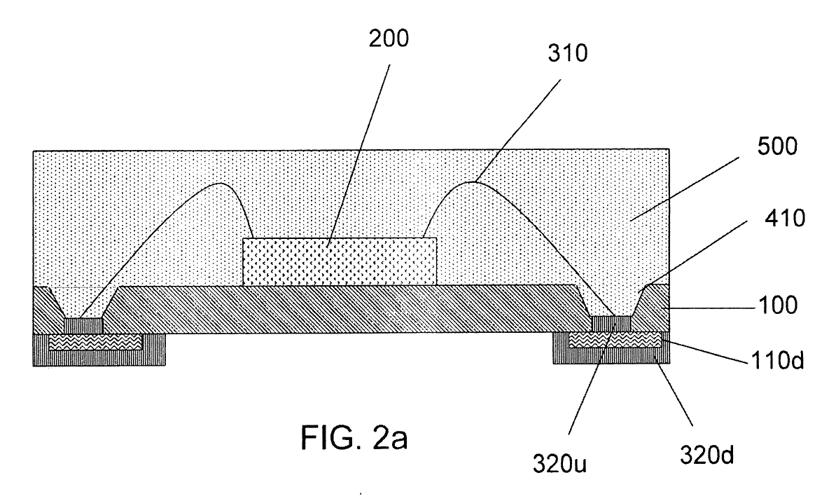

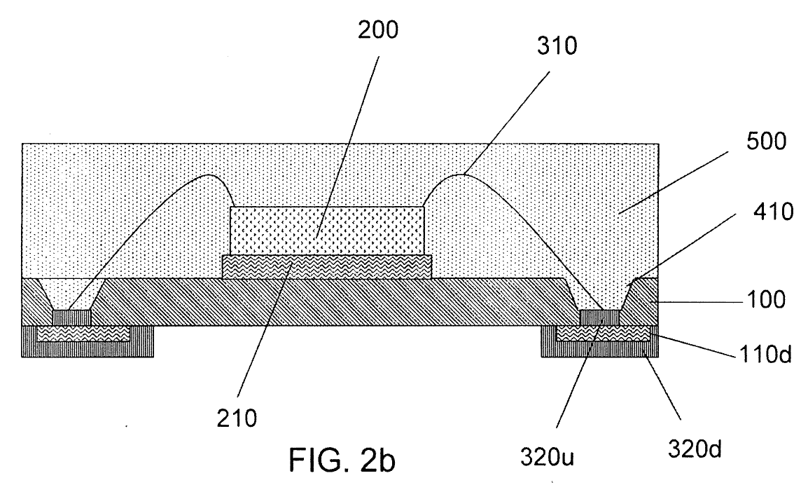

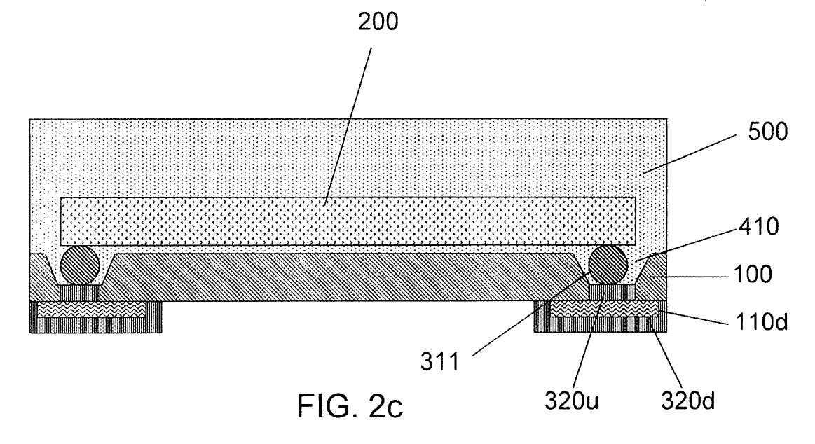

The embodiments in FIGS. 2a-2c show the package structures on a package carrier without the internal trace, and the internal bonding pads 320u are directly formed inside the blind holes 410 on the external traces 110d. The chip 200, shown in FIG. 2a, connects to internal bonding pads 320u via the metallic bonding wires 310. For a variant as FIG. 2b, the chip base 210 is interposed between the chip 200 and the substrate 100, and another variant as FIG. 2c, the metallic bonding wires is replaced by conductive balls 311 to reduce the thickness of the package structure further thereby.

Alternatively, the chip can be installed on the second surface and connect the external bonding pads via the conductive components directly.

It is not necessary to assign the material of the substrate. The substrate can be made by a copper clad laminate, an insulation substrate, a glass fiber substrate, a glass fiber prepreg, or a polymeric substrate. The conductive material inside the blind hole can be formed by electroplating a metal layer, filling metallic material or filling conductive glue, wherein the metal is copper usually. The internal and external traces are made of a conductive material, such as a metallic material or copper. The internal and external bonding pads should be made of the material having the features of high conductivity and anti-corrosiveness, such as gold, nickel, palladium, tin, lead, silver or an alloy thereof. The solder mask covering the external traces can be omitted. The conductive component, which connects the chip with the bonding pad, can be a metallic bonding wire or a conductive ball.

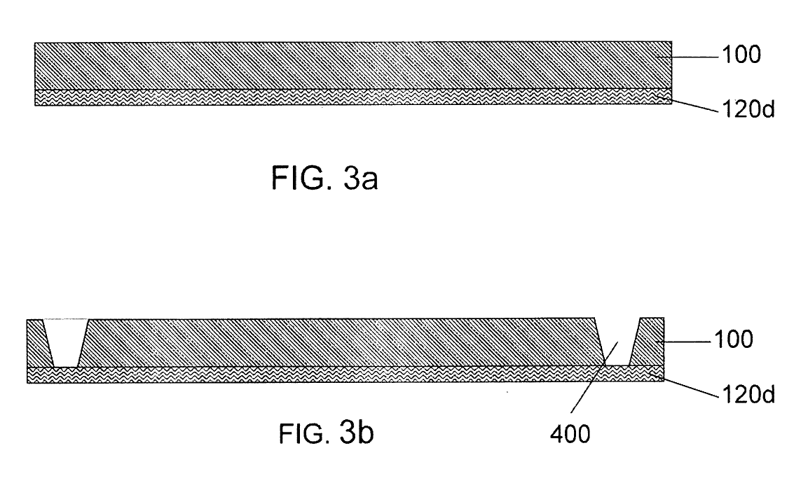

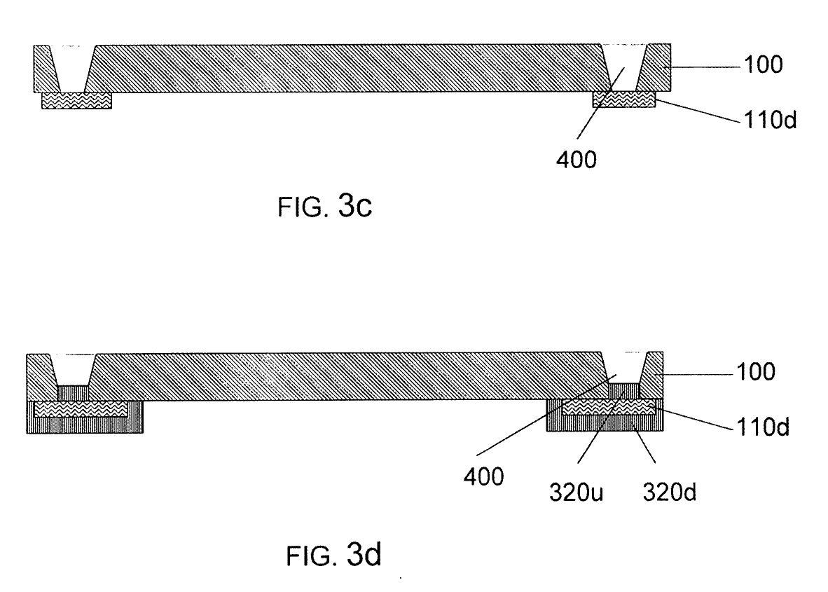

Accompanying with FIGS. 3a-3d, the process of making the carrier used in FIGS. 2a-2c decribed as following.

As FIG. 3a, a metal layer 120d is formed on a second surface of a substrate 100. Next, as FIG. 3b, blind holes 400 are formed. The blind hole 400 penetrates the substrate 100 from a first surface but the metal layer 120d. Refer to FIG. 3c. Continuously, as FIG. 3c, the metal layer 120d is processed to form external traces 110d, and every external trace 110d covers one blind hole 400. Finally, as FIG. 3d, internal bonding pads 320u are formed in blind holes 400 on the external traces 110d, and external bonding pads 320d are formed on and cover the external traces 110d.

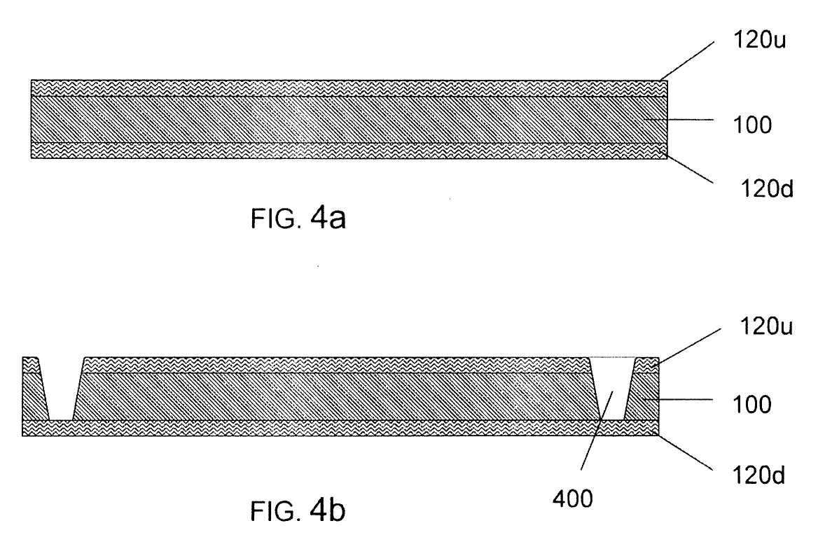

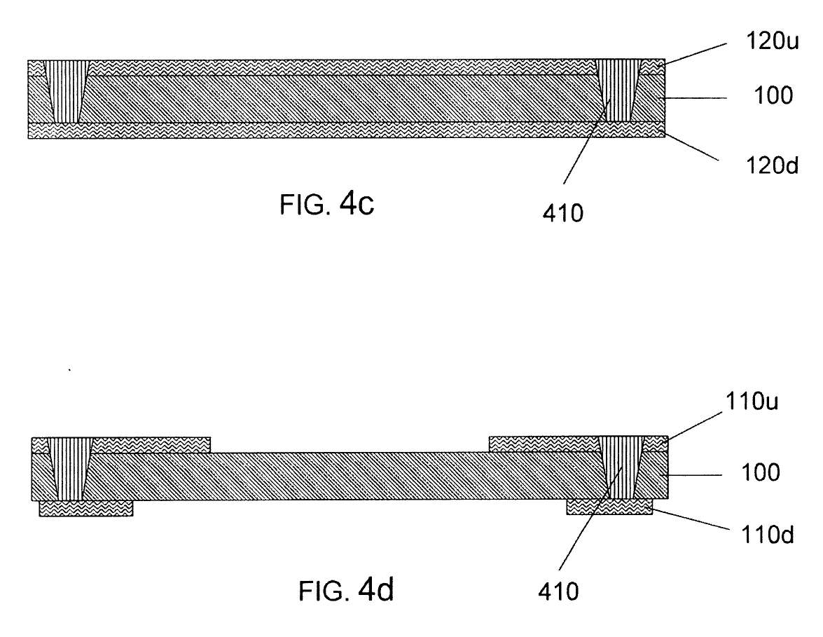

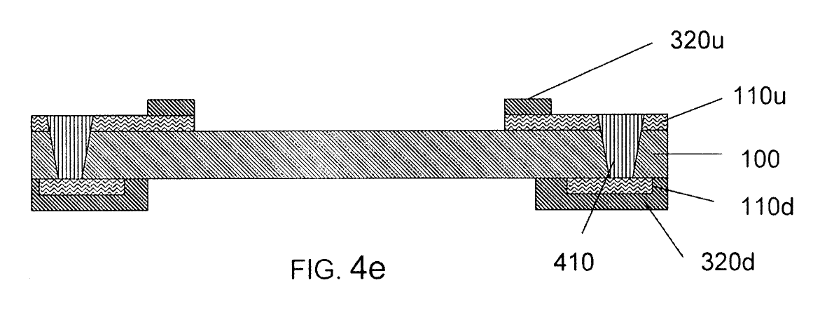

Accompanying with FIGS. 4a-4e, the process of making the carrier used in FIGS. 1a-1c decribed as following.

As FIG. 4a, a first metal layer 120u and a second metal layer 120d are formed on a first surface and a second surface of a substrate 100, respectively. Next, as FIG. 4b, blind holes 400 are formed. Every blind hole 400 penetrates the substrate 100 from the first metal layer 120u but the second metal layer 120d. Next, as FIG. 4c, a conductive material 410 is filled into the blind holes 400. Next, as FIG. 4d, the first metal layer 120u and the second metal layer 120d are respectively processed to form internal traces 110u and external traces 110d. Then, as FIG. 4e, internal bonding pads 320u are formed on the internal traces 110u and external bonding pads 320d are formed on the external traces 110d, respectively.

The conductive material in the blind hole can be formed by an electroplating method, a sputtering method, a vapor deposition method or an electrodeless plating method. The blind hole can be formed by a plasma method, a depth-control method, an image-transfer method or a laser-drilling method.

The embodiments described above are to exemplify the present invention to enable the persons skilled in the art to understand, make and use the present invention. However, it is not intended to limit the scope of the present invention. Therefore, any equivalent modification or variation according to the spirit of the present invention is to be also included within the scope of the present invention.

1. A chip package carrier, comprising:
a substrate having at least one blind hole penetrating said substrate;
at least one external trace formed on a second surface of said substrate and each covering one said blind hole; and
at least one external bonding pad formed and each being on one of said external traces.

2. The chip package carrier according to claim 1, wherein said external trace is made of a metallic material.

3. The chip package carrier according to claim 2, wherein said metallic material is copper.

4. The chip package carrier according to claim 1, wherein said substrate is made of a copper clad laminate, an insulation substrate, a glass fiber substrate, a glass fiber prepreg, and a polymeric substrate.

5. The chip package carrier according to claim 1, wherein said external bonding pad is made of gold, nickel, palladium, tin, lead, silver or a combination thereof.

6. The chip package carrier according to claim 1, wherein said external bonding pad covers said external trace corresponding thereto.

7. The chip package carrier according to claim 1 further comprising at least one internal bonding pad formed and each being inside one of said blind holes on one of said external traces.

8. The chip package carrier according to claim 7, wherein said internal bonding pad is made of gold, nickel, palladium, tin, lead, silver or a combination thereof.

9. The chip package carrier according to claim 7, wherein a chip is installed on a first surface of said substrate, and conductive components are used to connect said chip with said internal bonding pads.

10. The chip package carrier according to claim 9 further comprising a chip base interposed between said chip and said first surface.

11. The chip package carrier according to claim 9 further comprising an encapsulant covering said chip and said conductive components.

12. The chip package carrier according to claim 9, wherein said conductive component is a metallic bonding wire or a conductive ball.

13. The chip package carrier according to claim 1 further comprising at least one internal trace and a conductive material, wherein each said internal trace is formed on a first surface of said substrate and has an opening located above one said blind hole, and said conductive material is set inside said blind holes.

14. The chip package carrier according to claim 13, wherein said internal trace is made of a metallic material.

15. The chip package carrier according to claim 13, wherein said conductive material is a conductive glue.

16. The chip package carrier according to claim 13 further comprising at least one internal bonding pad formed and each being on one of said internal traces.

17. The chip package carrier according to claim 16, wherein said internal bonding pad is made of gold, nickel, palladium, tin, lead, silver or a combination thereof.

18. The chip package carrier according to claim 13, wherein a chip is installed on said first surface, and conductive components are used to connect said chip with said internal bonding pads.

19. The chip package carrier according to claim 18 further comprising an encapsulant covering said chip, said conductive components and said internal bonding pads.

20. The chip package carrier according to claim 18, wherein said conductive component is a metallic bonding wire.

21. The chip package carrier according to claim 13, wherein a chip is installed on said second surface and connects with said external bonding pad via a conductive component.

22. The chip package carrier according to claim 21 further comprising an encapsulant covering said chip, said conductive component and said external bonding pad.

23. The chip package carrier according to claim 21, wherein said conductive component is a metallic bonding wire.

24. A method for fabricating a chip package carrier, comprising steps:
providing a substrate
forming a second metal layer on a second surface of said substrate;
forming at least one blind hole and each penetrating said substrate but not penetrating said second metal layer;
processing said second metal layer into at least one external trace and each covering one of said blind holes; and
forming at least one external bonding pad on said external traces.

25. The method for fabricating a chip package carrier according to claim 24, wherein said blind hole is formed via a plasma method, a depth-control method, an image-transfer method, or a laser-drilling method; depth of said blind hole is controlled not to penetrate said second metal layer.

26. The method for fabricating a chip package carrier according to claim 24 further comprising a step: forming at least one internal bonding pad on said external traces located inside said blind holes.

27. The method for fabricating a chip package carrier according to claim 24 further comprising two steps: forming a first metal layer on a first surface of said substrate before forming said blind holes; and processing said first metal layer into at least one internal trace after forming said blind holes.

28. The method for fabricating a chip package carrier according to claim 27 further comprising a step: setting a conductive material into said blind holes.

29. The method for fabricating a chip package carrier according to claim 28, wherein said conductive material is set into said blind holes via an electroplating method, a sputtering method, a vapor deposition method, or an electrodeless plating method, or via filling said conductive material into said blind holes.

30. The method for fabricating a chip package carrier according to claim 28, wherein said conductive material is set into said blind holes via filling a conductive glue into said blind holes.

31. The method for fabricating a chip package carrier according to claim 27 further comprising a step: forming at least one internal bonding pad on said internal traces.
